(19) United States
(12) Patent Application Publication
(10) Pub. No.: US 2011/0084712 A1
(43) Pub. Date: Apr. 14, 2011

(54) CURRENT DIVIDER RESISTANCE IMAGING OF AN ELECTRICAL DEVICE USING AN ATOMIC FORCE PROBE

(75) Inventors: David E. Albert, Hopewell Junction, NY (US); Kari Satorius, Hopewell Junction, NY (US)

(73) Assignee: INTERNATIONAL BUSINESS MACHINES CORPORATION, Armonk, NY (US)

(21) Appl. No.: 12/576,294

(22) Filed: Oct. 9, 2009

(51) Int. Cl. G01R 27/08

(52) U.S. Cl. 324/691

(57) ABSTRACT

A method of analyzing an electronic device includes grounding a first end of an electrical structure, grounding a second end of the electrical structure, contacting an atomic force probe (AFP) to the electrical structure between the first and second ends, shifting the AFP across the electrical structure between the first and second ends, measuring an electrical property of the electrical structure at one of the first and second ends, and creating an image of the electrical structure based on the electrical property.

### BACKGROUND

The present invention relates to electrical testing of resistance and, more particularly, to a system and method including an atomic force probe for analyzing and imaging resistance of an electrical device.

Often times it is necessary to perform testing on electronic chips/semiconductors. Tests are performed as a final quality check during production or to isolate a problem that has developed in an electronic device or structure. During production it is particularly important to determine the location of a defect so that corrective measures can be taken to prevent additional defects from occurring. Present techniques for testing electronic chips, such as semiconductor wafers, include a focused ion beam (FIB) voltage contrast test, a scanning electron microscope (SEM) voltage contrast test, an SEM specimen absorbed current test, and a laser based stimulation localization test.

The FIB voltage contrast test is only applicable to electrically open structures typically above 500 Mohms. The test is not suitable for detecting moderately high resistances. In addition, during analysis, the focused ion beam mills away a portion of the sample. Thus, the FIB test is destructive and, once performed, the sample cannot be subjected to any additional testing. SEM voltage contrast tests are also only applicable to testing for electrically open structures. This test requires the presence of electrical probes within the SEM, or sample preparation to ground the electrical structure of interest. In addition, SEM testing requires that the test be performed in a vacuum. The SEM specimen absorbed current test is applicable to electrically open and resistive structures. To perform this test, electrical probes are required within the SEM. In addition to requiring specific probes and a vacuum environment, SEM testing causes damage, both physical and electrical, to the sample being tested. Finally, the laser based stimulation tests uses visible or IR lasers to modulate the electrical properties of the sample being tested. The magnitude of the electrical variation is displayed as an image. Unfortunately, this test does not provide acceptable spatial resolution even when solid immersion lenses are employed.

### SUMMARY

According to one exemplary embodiment, a method of analyzing an electronic device includes grounding a first end of an electrical structure, grounding a second end of the electrical structure, contacting an atomic force probe (AFP) to the electrical structure between the first and second ends, shifting the AFP across the electrical structure between the first and second ends, measuring an electrical property of the electrical structure at one of the first and second ends, and creating an image of the electrical structure based on the electrical property as measured at the second end of the electrical structure.

System and computer program products for analyzing and imaging the resistance of an electrical device are also described and claimed herein.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter, which is regarded as the invention, is particularly pointed out and distinctly claimed in the claims at the conclusion of the specification. The forgoing and other features, and advantages of the invention are apparent from the following detailed description taken in conjunction with the accompanying drawings in which:

FIG. 1 is a block diagram of an electrical structure including an electrical system being tested by an atomic force probe (AFP) in accordance with an exemplary embodiment;

FIG. 2 is an AFP topographic image of the electrical system of the device of FIG. 1;

FIG. 3 is a current divider resistance image of the electrical device of FIG. 2, illustrating a defect in the electrical system; and

FIG. 4 is a block diagram of a general-purpose computer linked to an atomic force probe configured and disposed to test the resistance of an electrical structure of an electrical sample in accordance with an exemplary embodiment.

### DETAILED DESCRIPTION

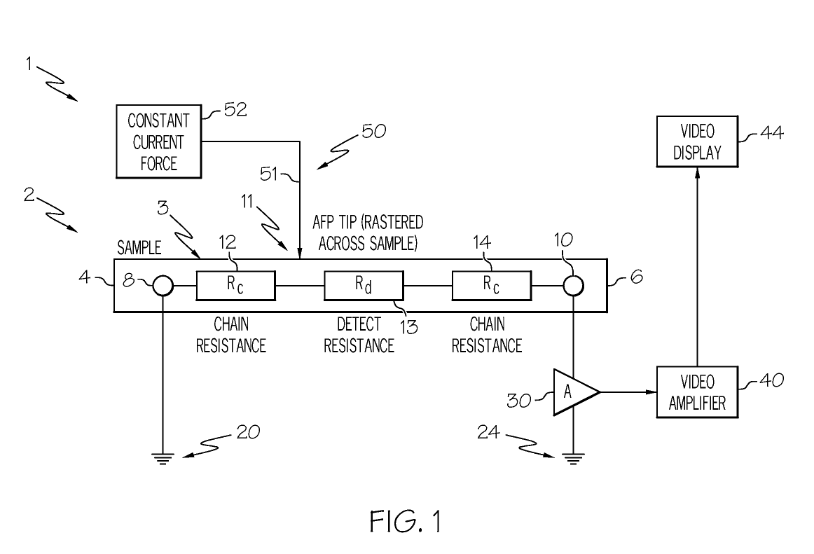

With reference now to FIG. 1, exemplary embodiments of the invention are directed to an apparatus 1 for testing an electrical sample such as indicated generally at 2. Electrical sample 2 includes a main body 3 bounded between a first end 4 and a second end 6. A first terminal 8 is arranged at first end 4 and a second terminal 10 is positioned at second end 6. An electrical structure 11 extends between first and second terminals 8 and 10. In the exemplary embodiment shown, electrical structure 11 takes the form of a plurality of resistances 12-14. Resistances 12 and 14 embody and represent normal and expected resistance of electrical structure 11. Resistance 13 embodies and represents normal and expected resistance of a defect or anomaly within electrical structure 11. Of course, it should be understood, that the type and nature of the electrical structure can vary. As further shown in FIG. 1, first terminal 8 is connected to a first ground 20 and second terminal 10 is connected to a second ground 24 through a current amplifier 30. With this arrangement, electrical structure 11 is subjected to current divider resistance testing to image and characterize the location of defect resistance 13 as will be discussed more fully below.

In a current divider test, a current is applied to a structure being tested. The current flows to ground through two known resistance paths. The current flow is measured, and a determination is made whether the resistance in one or the other of the paths is correct. Too high of a resistance segregates the applied current to one end of the structure being tested. As will be discussed more fully below, apparatus 1 is shifted (rastered) across main body 3 between the plurality of resistances 12-14 to measure current flow at various points. In the exemplary embodiment shown, current will flow through resistances 12-14 to a current amplifier 30 arranged between second terminal 10 and ground 24. Current amplifier 30 is operationally coupled to a video amplifier 40, which, in turn, is coupled to a video display 44.

In accordance with the exemplary embodiment, apparatus 1 takes the form of an atomic force probe 50 having a probe tip 51 operationally coupled to a constant current force supply 52. Of course it should be understood that a constant voltage supply could also be employed. Probe tip 51 is configured and disposed to shift/raster across electrical structure 11 applying a constant current force 52 through electrical structure 11. More specifically the constant current force 52 is passed through each of resistances 12-14. The constant current flows to ground 20 and ground 24. In the event that defect resistance 13 is too high, current will disproportionately flow to one of ground 20 and 24.

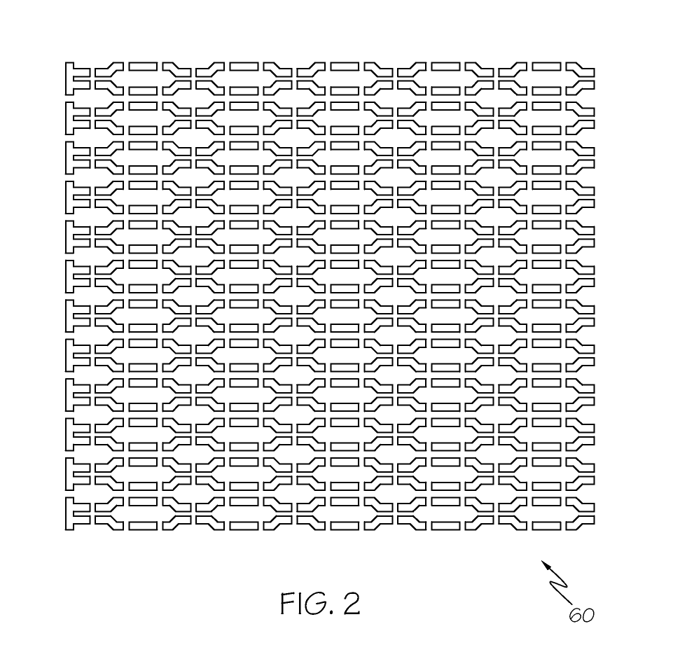

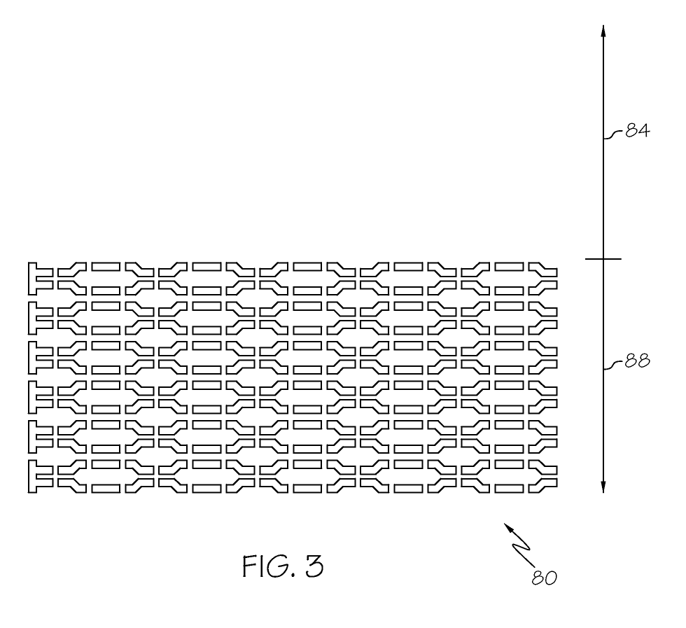

In accordance with one aspect of the invention, atomic force probe 50 will shift across electrical structure 11 in a first direction along, across and/or between resistances 12-14 and in a second direction, substantially orthogonal relative to the first direction. Initially, the atomic force probe creates a topography image, such as indicated at 60 in FIG. 2, of a portion of electrical structure 11. The topography image shows the location of an electrical pattern, i.e. all of resistances that make up electrical structure 11 of electrical device 2. At the same time, the atomic force probe creates an electrical property image, such as indicated at 80 in FIG. 3, of electrical structure 11. Electrical property image, in accordance with an exemplary embodiment, is a current divider resistance image indicating that a defect that alters the response between a portion 84 of electrical structure 11, and a portion 88 of electrical structure 11 exists. That is, the current flowing from tip 51 through resistance 14 passes to ground 24 through current amplifier 30, where the measured current is further amplified and converted to a voltage based signal. The voltage based signal is further amplified in video amplifier 40 and adjusted to provide an image on a video display indicating the location of defect resistance 13 within electrical structure 11. With this arrangement, the atomic force probe performs an analysis of the electrical structure without altering electrical device 2. In addition, the use of an atomic force probe allows testing to be conducted at atmospheric pressures while providing spatial resolutions and resistance sensitivities that are higher than other available testing techniques.

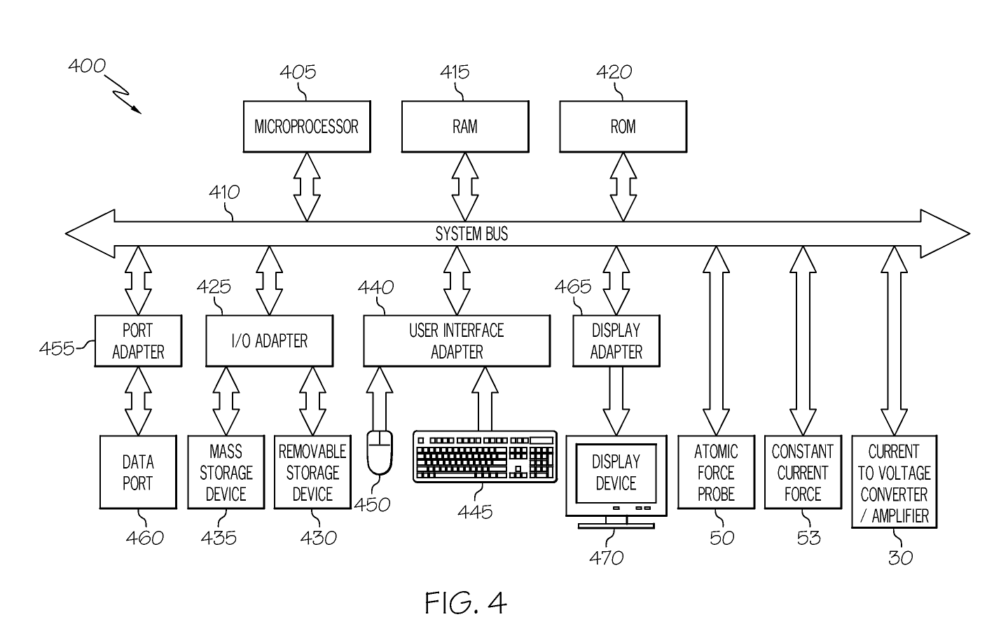

The method of testing electrical structure 11 described herein can also be practiced with a general-purpose computer such as illustrated at 400 in FIG. 4 and the method may be coded as a set of instructions on removable or hard media for use by the general-purpose computer 400. In FIG. 4, computer system 400 has at least one microprocessor or central processing unit (CPU) 405. CPU 405 is interconnected via a system bus 410 to a random access memory (RAM) 415, a read-only memory (ROM) 420, an input/output (I/O) adapter 425 for connecting a removable data and/or program storage device 430, a mass data and/or program storage device 435, a user interface adapter 440 for connecting a keyboard 445 and a mouse 450, a port adapter 455 for connecting a data port 460, a display adapter 465 for connecting a display device 470, atomic force probe 50 configured and disposed to test an electrical structure of an electrical device as well as electrical constant current force 52 and current-to-voltage amplifier 30.

ROM 420 contains the basic operating system for computer system 400. The operating system may alternatively reside in RAM 415 or elsewhere as is known in the art. Examples of removable data and/or program storage device 430 include magnetic media such as floppy drives and tape drives and optical media such as CD ROM drives. Examples of mass data and/or program storage device 435 include hard disk drives and non-volatile memory such as flash memory. In addition to keyboard 445 and mouse 450, other user input devices such as trackballs, writing tablets, pressure pads, microphones, light pens and position-sensing screen displays may be connected to user interface 440. Examples of display devices include cathode-ray tubes (CRT) and liquid crystal displays (LCD).

A computer program with an appropriate application interface may be created by one of skill in the art and stored on the system or a data and/or program storage device to simplify the practicing of this invention. In operation, information for or the computer program created to run the present invention is loaded on the appropriate removable data and/or program storage device 430, fed through data port 460 or typed in using keyboard 445.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one ore more other features, integers, steps, operations, element components, and/or groups thereof.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A method of analyzing an electronic device, the method comprising:
grounding a first end of an electrical structure;
grounding a second end of the electrical structure;
contacting an atomic force probe (AFP) with a constant current force and or constant voltage to the electrical structure between the first and second ends;
shifting the AFP across the electrical structure between the first and second ends;
measuring an electrical property of the electrical structure at one of the first and second ends; and
creating an image of the electrical structure based on the electrical property.

2. The method of claim 1, wherein creating an image of the electrical structure includes creating one of a topographical image and a resistance image.

3. The method of claim 1, wherein shifting the AFP across the electrical structure including shifting the AFP in a first direction and in a second direction, the second direction being substantially orthogonal relative to the first direction.

4. The method of claim 1, further comprising: applying a constant current force to the electrical structure through the AFP.

5. The method of claim 4, wherein measuring the electrical property of the electrical structure includes measuring current flowing to one of the first and second ends.

6. A system for analyzing resistance of an electrical structure, the system comprising:
a central processing unit (CPU), said CPU being interconnected functionally via a system bus to:
an atomic force prober (AFP)
an input/output (I/O) adapter connecting to at least one of a removable data storage device, a program storage device, and a mass data storage device;
a display adapter connecting to a display device; and
at least one memory device thereupon stored a set of instructions which, when executed by said CPU, causes said system to:
shift the AFP across an electrical structure between a first end and second end;
measure an electrical property of the electrical structure at one of the first and second ends; and
create an image of the electrical structure based on the electrical property.

7. The system according to claim 6, wherein the set of instructions, which, when executed by said CPU, causes said, system to: generate a topography image of the electrical structure.

8. The system according to claim 7, wherein the set of instructions, which, when executed by said CPU, causes said, system to: generate a resistance image of the electrical structure.

9. The system of claim 6, wherein the set of instructions, which, when executed by said CPU, causes said, system to: shift the AFP across the electrical structure in a first direction and in a second direction, the second direction being substantially orthogonal relative to the first direction.

10. The system according to claim 6, wherein the set of instructions, which, when executed by said CPU, causes said, system to: apply one of a constant current force and constant voltage source to the electrical structure through the AFP.

11. The system according to claim 10, wherein the set of instructions, which, when executed by said CPU, causes said, system to: measure current flowing to one of the first and second ends.

12. A computer program product comprising:
a computer useable medium including a computer readable program, wherein the computer readable program when executed on a computer causes the computer to:
shift an atomic force prober (AFP) across an electrical structure between a first end and second end;
measure an electrical property of the electrical structure at one of the first and second ends; and
create an image of the electrical structure based on the electrical property.

13. The computer program product according to claim 12, wherein the computer readable program when executed on a computer causes the computer to: generate a topography image of the electrical structure.

14. The computer program product according to claim 12, wherein the computer readable program when executed on a computer causes the computer to: generate a resistance image of the electrical structure.

15. The computer program product according to claim 12, wherein the computer readable program when executed on a computer causes the computer to: shift the AFP across the electrical structure in a first direction and in a second direction, the second direction being substantially orthogonal relative to the first direction.

16. The computer program product according to claim 12, wherein the computer readable program when executed on a computer causes the computer to: apply one of a constant current force and a constant voltage source to the electrical structure through the AFP.

17. The computer program product according to claim 16, wherein the computer readable program when executed on a computer causes the computer to: measure current flowing to one of the first and second ends.
